(19) United States
(12) Patent Application Publication
(10) Pub. No.: US 2020/0312725 A1
(43) Pub. Date: Oct. 1, 2020

(54) METHOD OF FORMING A SEMICONDUCTOR DEVICE

(71) Applicant: IMEC vzw, Leuven (BE)

(72) Inventors: Anabela Veloso, Leuven (BE); Trong Huynh Bao, Leuven (BE); Julien Ryckaert, Schaerbeek (BE); Raf Appeltans, Haasrode (BE)

(21) Appl. No.: 16/836,478

(22) Filed: Mar. 31, 2020

(30) Foreign Application Priority Data
Apr. 1, 2019 (EP) 19166623.9

(51) Int. Cl. H01L 21/8234

(52) U.S. Cl. CPC H01L 21/823487; H01L 21/823412

(57) ABSTRACT

The disclosed technology relates to methods of fabricating field-effect transistors having channels extending in horizontal and vertical directions. According to an aspect, a method comprises: providing a semiconductor substrate comprising: in a vertical channel field-effect transistor (FET) device region, a first layer structure comprising a lower semiconductor layer, an intermediate semiconductor layer above the lower semiconductor layer and an upper semiconductor layer above the intermediate semiconductor layer, and, in a horizontal channel FET device region, a second layer structure comprising at least one semiconductor layer, wherein the first layer structure and the second layer structure have different compositions and wherein a surface of the substrate in the vertical channel FET device region is coplanar with a surface of the substrate in the horizontal channel FET device region; forming a mask defining a first semiconductor structure mask portion above the vertical channel FET device region and a second semiconductor structure mask portion above the horizontal channel FET device region; and patterning the first layer structure and the second layer structure by simultaneously etching the first layer structure and the second layer structure while using the mask as an etch mask, thereby forming: a first semiconductor structure for a vertical channel FET device in the vertical channel FET device region, the first semiconductor structure comprising a lower layer portion, an intermediate layer portion and an upper layer portion, and a second semiconductor structure for a horizontal channel FET device in the horizontal channel FET device region.

### CROSS-REFERENCE TO RELATED APPLICATIONS

This application claims foreign priority to European Patent Application No. EP 19166623.9, filed Apr. 1, 2019, the content of which is incorporated by reference herein in its entirety.

### BACKGROUND

### Field

The disclosed technology generally relates to methods of fabricating a semiconductor device, and more particularly to methods of fabricating field-effect transistors having channels extending in horizontal and vertical directions.

### Description of the Related Technology

In the strive to provide even more power- and area-efficient circuit designs, new transistor devices are being developed. Two types of non-planar field-effect transistor (FET) devices are horizontal channel FET devices and vertical channel FET devices.

Some horizontal channel FET devices include finFETs having a gate straddling a channel portion of a fin-shaped semiconductor structure, and horizontal nanowire- or nanosheet-FET (horizontal NWFET or NSFET) devices having a gate at least partly enclosing a channel portion of a horizontally oriented nanowire- or nanosheet-shaped semiconductor structure.

Vertical channel FET devices (also referred to as VFET devices) include vertical nanowire- or nanosheet-FET (vertical NWFET or NSFET) devices having a gate at least partly enclosing a channel portion of a vertically oriented nanowire or nanosheet semiconductor structure.

Efficient process flows dedicated to fabrication of either horizontal channel FET devices or vertical channel FET devices have been developed. However, due to the different designs of the horizontal and vertical device types, time efficient and/or cost-effective fabrication of horizontal channel FET devices and vertical channel FET devices on a common substrate remains a challenge. Although fabrication of horizontal channel FET devices and vertical channel FET devices may involve corresponding process steps, such as patterning horizontal or vertical semiconductor structures for the respective FET devices, gate formation, source/drain definition etc., the design differences between the device types would seem to suggest that co-integration of horizontal and vertical channel FET devices on a common substrate is best suited for a purely sequential approach, e.g., wherein the process steps for horizontal and vertical channel FET device fabrication are performed in a staggered fashion.

### SUMMARY OF CERTAIN INVENTIVE ASPECTS

A sequential approach however implies duplication of similar process steps, first in a horizontal channel FET device region and then in a vertical channel FET device region, or vice versa. This however adds to the overall costs and complexity of the process and hence inhibits time efficient and/or cost-effective fabrication on a large scale. Therefore, as realized by the inventors, it would be desirable to find processing schemes which would allow at least some of the device fabrication steps to be applied simultaneously in the horizontal and vertical channel FET device regions.

An objective of the disclosed technology is therefore to provide a method allowing co-integration of vertical and horizontal channel FET devices on the same substrate with improved process- and cost-efficiency.

According to an aspect of the disclosed technology there is provided a method of fabricating a semiconductor device, the method comprising:
providing a semiconductor substrate comprising:
   in a vertical channel field-effect transistor, FET, device region, a first layer structure comprising a lower semiconductor layer, an intermediate semiconductor layer above the lower semiconductor layer and an upper semiconductor layer above the intermediate semiconductor layer, and,
   in a horizontal channel FET device region, a second layer structure comprising at least one semiconductor layer,
   wherein the first layer structure and the second layer structure have different compositions and wherein a surface of the substrate in the vertical channel FET device region is coplanar with a surface of the substrate in the horizontal channel FET device region;
forming a mask defining a first semiconductor structure mask portion above the vertical channel FET device region and a second semiconductor structure mask portion above the horizontal channel FET device region; and
patterning the first layer structure and the second layer structure by simultaneously etching the first layer structure and the second layer structure while using the mask as an etch mask, thereby forming:
   a first semiconductor structure for a vertical channel FET device in the vertical channel FET device region, the first semiconductor structure comprising a lower layer portion, an intermediate layer portion and an upper layer portion, and
   a second semiconductor structure for a horizontal channel FET device in the horizontal channel FET device region.

As realized by the inventors, an underlying impediment to parallel or simultaneous processing in horizontal and vertical channel FET device regions stems in part from the different geometries and compositions of the semiconductor structures for the two types of FETs. For example, the semiconductor structure for vertical channel FET devices may advantageously be formed with a multi-layered composition (e.g., a lower, intermediate and upper layer), e.g., to allow improved control over gate length definition and to allow selective channel thinning, to name a few advantages. Typically, the intermediate layer may be formed of a semiconductor material which is different from a material of the lower layer and a material of the upper layer. Meanwhile, the semiconductor structure for horizontal channel FET devices may, depending on the particular application. either have a single-layered composition (e.g., for finFET), a double-layered composition of a sacrificial layer and a channel layer (for a horizontal NWFET or NSFET) or even a multi-layered composition of alternating sacrificial and channel layers (for multi-channel or vertically stacked horizontal NWFETs or NSFETs).

According to some embodiments, there is provided a semiconductor substrate comprising first and second layer structures of different compositions in the vertical channel FET device region (hereinafter “VFET region”) and the horizontal channel FET device region (hereinafter “HFET region”), respectively. Accordingly, the first and second layer structures may be individually tailored for the vertical and horizontal FET devices, respectively.

In addition, since the respective surfaces of the VFET and HFET regions are co-planar, the respective surfaces may together define a common planar substrate surface. This in turn allows the first and second layer structures to be simultaneously patterned using a common etch mask, despite their different compositions.

Subsequent to forming the first and second semiconductor structures, the method may proceed with further process steps to complete forming of the vertical and horizontal FET devices in their respective regions.

As described herein, a horizontal channel FET device refers herein to a device comprising a semiconductor structure comprising a first and a second source/drain portion and a channel portion located intermediate and extending horizontally between the first and second source/drain portions, and further comprising a gate structure extending horizontally along the channel portion. In a horizontal channel FET device, the first and second source/drain portions and the channel portion intersect a common horizontal plane. The channel portion is adapted to (in use of the device) conduct a horizontally oriented flow of charge carriers between the source/drains.

As described herein, a vertical channel FET device refers herein to a device comprising a semiconductor structure comprising a lower and an upper source/drain portion and a channel portion located intermediate and extending vertically between the lower and upper source/drain portions, and further comprising a gate structure extending vertically along the channel portion. The gate structure may at least partially enclose the channel portion. In particular, the gate structure may wrap-around the channel portion, in other words forming a gate-all-around (GAA) structure. The lower and upper source/drain portions and the channel portion may intersect a common vertical plane. The channel portion is adapted to (in use of the device) conduct a vertically flow of charge carriers between the source/drains.

As used herein, vertical direction or orientation (e.g., of a surface, a dimension or other feature) refers to a direction or orientation that is substantially parallel to a normal to a major surface of the substrate (e.g., a main plane of extension or main/upper surface thereof). On the other hand, horizontal direction or orientation refers to a direction or orientation that is substantially parallel to the major surface of the substrate (e.g., a main plane of extension or main surface thereof), or equivalently transverse to the vertical direction. Meanwhile, terms such as “above”, “upper”, “top” and “below”, “lower”, “bottom” refer to relative positions as viewed along the vertical direction, and does hence not imply an absolute orientation of the substrate or device.

The compositions of the first and second layer structures may at least differ by having a different number of layers, or by the first layer structure comprising at least one layer formed of a different material than the second layer structure. In case the first and second layer structures have the same number of layers, the compositions of the layer structures may differ in that a vertical level of an interface between an adjacent pair of layers of the first layer structure falls within a layer of the second layer structure.

The simultaneous etching may comprise etching back exposed surface portions of the first and second layer structures to corresponding vertical levels, such that the first and second semiconductor structures present corresponding heights above a common vertical level.

This may further simplify subsequent processing steps of device formation in that both the upper surfaces of the VFET and HFET regions (defined by the upper surfaces of the first and semiconductor structures) will be located at corresponding levels and the bottom (etched-back) surfaces of the VFET and HFET regions (adjacent to the first and second semiconductor structures) will be located at corresponding levels. The exposed surface portions of the first and second layer structures here refer to the horizontally oriented surface portions exposed by the etch mask.

The etching back of the exposed surface portions may be performed at a substantially uniform/same rate in the VFET and HFET regions. Hence, the exposed surface portions in the VFET and HFET may be etched back by corresponding vertical distances.

At least some of the layers of the first layer structure may be epitaxially grown semiconductor layers and the second layer structure may comprise at least two epitaxially grown semiconductor layers, wherein the method may further comprise recessing the substrate in at least one of the vertical channel FET device region or the horizontal channel FET device region such that an upper surface of the epitaxially grown layers of the first semiconductor structure and an upper surface of the epitaxially grown layers of the second layer structure form co-planar upper surfaces. Hence, any height/thickness difference between the first and second layer structures may be compensated for by a preceding recessing step of either the VFET region or the HFET region.

Alternatively, forming the first layer structure in the vertical channel FET device region may comprise:
recessing the substrate in the vertical channel FET device region, and
subsequently epitaxially growing the first layer structure comprising lower, intermediate and upper semiconductor layers such that an upper surface of the first layer structure becomes coplanar with the surface of the substrate in the horizontal channel FET device region.

This approach is especially advantageous in case the second layer structure in the HFET region has a single semiconductor layer. The vertical space required for the first layer structure may conveniently be provided by recessing the substrate by a corresponding vertical distance.

The method may further comprise forming a mask covering the substrate in the HFET region and exposing the substrate in the VFET region, and using the mask as an etch mask during the recessing of the substrate in the VFET region, and further as a growth mask during the epitaxial growing of the first layer structure in the VFET region. The mask may be formed by an oxide.

The method may further comprise, prior to growing the first layer structure, forming an insulating layer on a sidewall of the substrate formed during said recessing of the substrate.

An electrical insulation may thereby be provided between the VFET region and the HFET region. Moreover, epitaxial growth on the sidewall may be counteracted.

The method may further comprise forming, in the vertical channel FET device region, a first gate structure for the vertical channel FET device, the first gate structure extending along a channel portion formed by an intermediate layer portion of the first semiconductor structure, and, in the horizontal channel FET device region, a second gate structure for the horizontal channel FET device, the second gate structure extending along a channel portion of the second semiconductor structure.

The method may further comprise forming a bottom insulating layer embedding a respective bottom portion of the first and second semiconductor structures and having an upper surface extending at a vertical level below the intermediate layer portion of the first semiconductor structure, and subsequently forming said gate structures on the bottom insulating layer.

The gate structures may hence be separated and insulated from the semiconductor substrate. By the upper surface of the insulating layer extending at a level below the intermediate layer portion, the entire intermediate layer portion may be exposed wherein the first gate structure may be formed to extend along the entire length thereof. Additionally, an upper section of the lower layer portion may be exposed which allows selective spacer formation thereon, as discussed below.

The method may further comprise recessing the first gate structure in the vertical channel FET device region to define a gate length for the vertical channel FET device.

Due the vertical channel orientation of the VFET, the gate/channel length is not defined by the linewidth of the gate but rather by the vertical dimension/thickness of the gate. Hence, by selectively recessing the first gate structure in the VFET region, the gate length may be defined independently from the gate length in the HFET region.

Upper surfaces of the first and second gate structures may, prior to the recessing, be located at corresponding vertical levels.

This allows the gate structures to be formed in parallel in the VFET region and the HFET region, e.g, by simultaneously depositing materials with a same thickness in the regions.

Forming the gate structures may comprise simultaneously patterning a gate layer formed in the vertical channel FET device region and in the horizontal channel FET device region.

Accordingly, the first and second gate structures may be formed in a parallel and efficient manner in the VFET and HFET regions by a common gate layer deposition and subsequent gate layer patterning. The patterning may be followed by the above-disclosed recessing of the first gate structure to define the gate length for the vertical channel FET device.

The above-mentioned gate structures may either be final gate structures (e.g., comprising a respective final gate dielectric and a respective final gate electrode) or sacrificial or dummy gate structures (e.g., comprising a respective sacrificial or dummy gate dielectric and a respective sacrificial or dummy gate).

According to a replacement metal gate (RMG) flow, the first and second gate structures may be sacrificial or dummy gate structures comprising a respective sacrificial or dummy gate, wherein the method may further comprise:
subsequent to recessing the sacrificial or dummy gate of the first sacrificial or dummy gate structure to define a gate length for the vertical channel FET device, embedding the first and second semiconductor structures in a dielectric layer having a height exposing an upper surface of the sacrificial or dummy gate of the second sacrificial or dummy gate structure and covering an upper surface of the recessed sacrificial or dummy gate of the first sacrificial or dummy gate structure;
forming a trench in the dielectric layer to expose the sacrificial or dummy gate of the vertical channel FET device region; and
simultaneously replacing the respective sacrificial or dummy gates of the first and second sacrificial or dummy gate structures with a respective gate electrode.

An RMG flow may hence be applied in parallel in the VFET and HFET regions.

The replacement of the respective sacrificial or dummy gates may comprise simultaneously removing the sacrificial or dummy gates of the first and second sacrificial or sacrificial or dummy gate structures by etching and subsequently depositing gate electrode material in the trench in the VFET region and in a trench in the dielectric layer formerly occupied by the sacrificial or dummy gate in the HFET regions.

The method may further comprise recessing the gate electrode material deposited in the trench in the vertical channel FET device region.

The intermediate layer may be formed of a material being different from a material forming the lower layer and a material forming the upper layer, and the method may further comprise, prior to forming the first gate structure, forming a spacer on peripheral surfaces of the lower layer portion and the upper layer portion.

As the intermediate layer is formed of a material being different from materials forming the lower and upper layers of the first pillar section a selective or at least preferential forming of the spacer on the upper and lower layer portions is enabled.

This facilitates the gate to be aligned vertically, in an accurate manner, with respect to the intermediate/channel layer portion. The spacer may separate a gate electrode of the first gate structure from the lower and upper layer portions. By forming the first gate structure to extend along the full height (e.g., the thickness) of the intermediate layer portion, the gate length may accordingly be defined to match the height of the intermediate layer portion.

Forming the spacer may comprise:
subjecting the first semiconductor structure to an oxidation process, thereby forming an oxide layer on the peripheral surfaces of the lower layer portion and the upper layer portion and on peripheral surfaces of the intermediate layer portion, such that the lower and upper layer portions are provided with thicker oxide layer portions than the channel portion.

A thickness of the spacer thus formed may accordingly be controlled via the duration of the oxidation process.

The method may further comprise reducing a thickness of the oxide layer by etching. Especially, the method may comprise etching the oxide layer to expose the channel portion while preserving at least some of the oxide layer (e.g., a thickness portion thereof) at the lower and upper layer portions.

The lower layer of the first semiconductor structure may comprise Si₁₋ₓGeₓ, the intermediate layer may comprise Si_{1-y}Ge_{y}, and the upper layer semiconductor may comprise Si_{1-z}Ge_{z}, wherein 0<x, z≤1 and 0≤y<x, z.

Accordingly, the lower, intermediate and lower layers may be Si-comprising layers wherein at least the lower and upper layers further comprise Ge, the Ge-content being greater than a Ge-content of the intermediate layer.

Especially, the intermediate layer may be a Si layer and the lower and upper layers may be SiGe layers, preferably with a Ge content in the range or 10 to 90%, or about 20 to 30%.

### BRIEF DESCRIPTION OF THE DRAWINGS

The above, as well as additional objects, features and advantages of the present inventive concept, will be better understood through the following illustrative and non-limiting detailed description, with reference to the appended drawings. In the drawings like reference numerals will be used for like elements unless stated otherwise.

FIGS. 1 to 24 illustrate perspective views of intermediate structures at various stages of fabrication according to a method for fabricating a semiconductor device, according to various embodiments.

### DETAILED DESCRIPTION OF CERTAIN ILLUSTRATIVE EMBODIMENTS

A method for forming a semiconductor device will now be described with reference to the figures. Reference will throughout be made to a vertical channel field-effect transistor (FET) device region (VFET region) 10 and a horizontal channel FET device region (HFET region) 20 of a semiconductor substrate 100, The VFET region 10 is a region for supporting vertical channel FET (VFET) devices. The HFET region 20 is a region for supporting horizontal channel FET (HFET) devices.

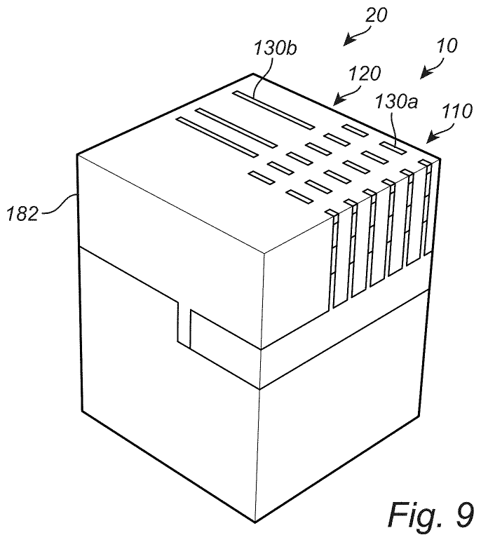

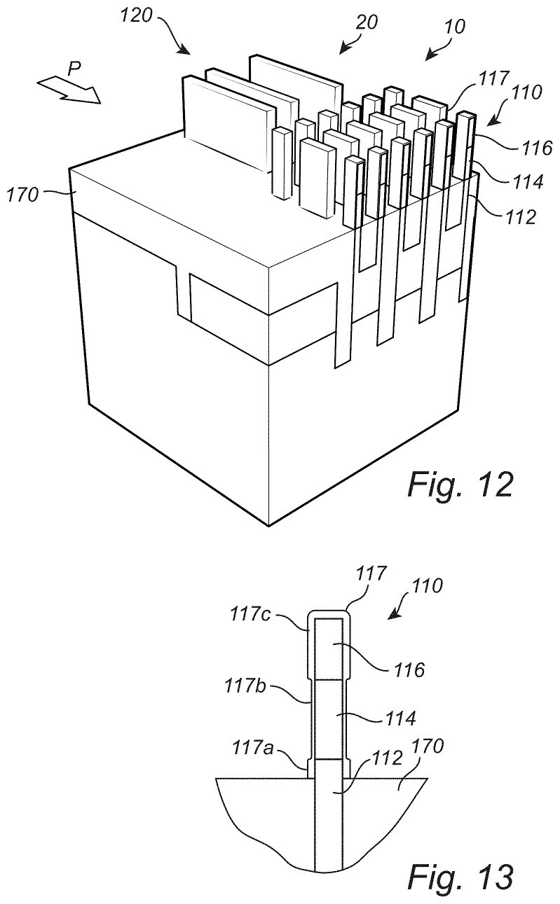

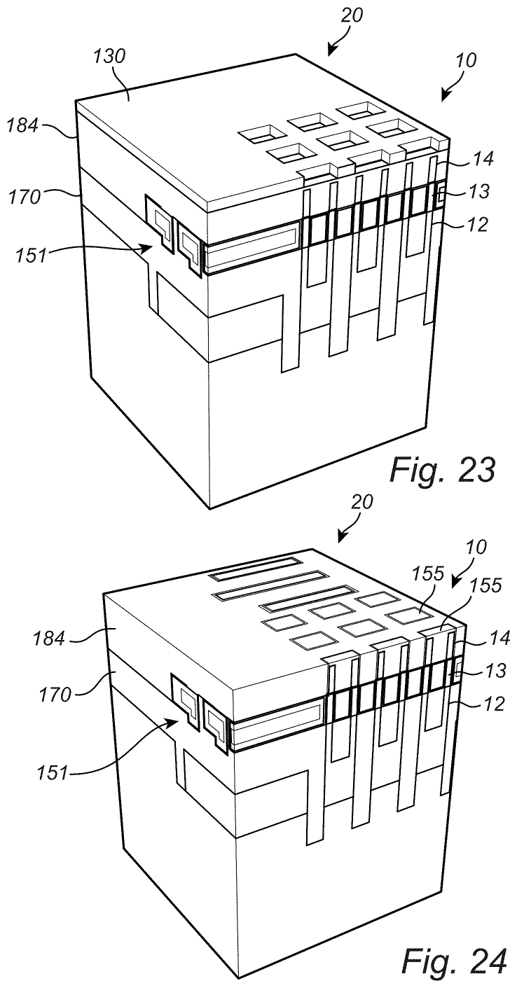

According to a general outline, the method may comprise substrate preparation (FIGS. 1-5), semiconductor structure patterning (FIGS. 6-8), bottom electrode layer partitioning in the VFET region (FIGS. 9-11), gate formation (FIGS. 12-22) and top contact formation (FIGS. 23-24). The method may comprise further process steps, as will be set forth in the following.

Unless stated otherwise, the figures show in perspective a section of the substrate 100 along a boundary between the VFET and HFET regions 10, 20. The illustrated planes of section extending through the substrate 100 are common to all the figures, unless indicated otherwise. As may be appreciated, the substrate 100 and the VFET and HFET regions 10, 20 may typically present a much greater lateral/horizontal extension than shown, beyond the illustrated section. It may further be noted that the relative dimensions of the shown structures, for instance the relative thickness of layers, is merely schematic and may, for the purpose of illustrational clarity, differ from a physical device structure.

### Substrate Preparation

FIGS. 1-5 show perspective views of intermediate structures illustrating process steps relating to the substrate preparation, which comprise providing first and second layer structures in the VFET region 10 and the HFET region 20, respectively.

FIG. 1 shows the starting substrate 100 for the process. The substrate 100 is a semiconductor substrate, e.g., a substrate comprising at least one semiconductor layer. The substrate 100 may be a single-layered semiconductor substrate, for instance formed by a bulk substrate. The substrate 100 may, however, also be a multi-layered substrate, for instance a substrate formed by an epitaxially grown semiconductor layer on a bulk substrate, or a semiconductor-on-insulator (SOI) substrate.

As further shown in FIG. 1, a mask layer 102 has been formed on the substrate 100. The mask layer 102 may for instance be an oxide layer (such as SiO₂, SiOC) or a nitride layer (such as SiN). The mask layer 102 may, for instance, be deposited using chemical vapor deposition (CVD) or atomic layer deposition (ALD). If the mask layer 102 is formed of SiO₂, the mask layer 102 may also be formed by oxidation.

A further mask 132 has been formed on the mask layer 102. The further mask 132 may for instance be a resist-based mask patterned using lithography. However, it is also possible to from the mask 132 from a lithographic mask layer stack (a “litho-stack”) comprising a number of mask layers (e.g., one or more anti-reflective coatings, organic spin-on layers and/or transfer layers, etc.) below a top-most resist-based layer, and patterned by transferring a lithographically defined pattern in the resist-based layer into the lower layers of the stack by etching.

In FIG. 2, the mask layer 102 has been patterned to define a mask 102 covering the substrate 100 in the HFET region 20 and exposing the substrate 100 in the VFET region 10. The mask 102 thus defines the respective horizontal dimensions of the VFET region 10 and the HFET region 20. The mask layer 102 may be patterned by etching while using the further mask 132 as an etch mask. A suitable wet- or dry-etching process allowing the mask layer 102 to be etched selectively with respect to the further mask 132 may be employed, wherein selective etching should be understood as etching such that exposed portions of the mask layer 102 may be removed while portions of the mask layer 102 masked by the further mask 132 may be preserved. The further mask 132 may be removed after the patterning of the mask layer 102.

As further shown in FIG. 2, the VFET region 10 of the substrate 100 has been recessed by etching the substrate 100 in the VFET region 10 while using the mask 102 as an etch mask. The substrate 100 may be recessed in the VFET region 10 to a depth such that a vertical separation between the upper surface of the recessed VFET region 10 and the upper surface of the HFET region 20 matches an intended height of the layer structure which is to be formed in the VFET region 10. Both wet- and dry-etching of the substrate 100 are possible.

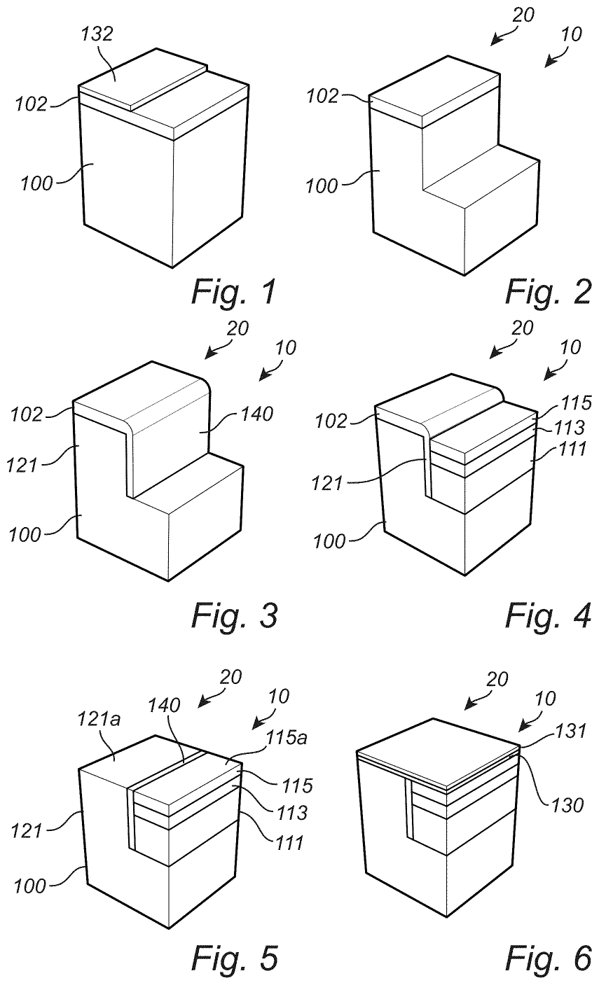

As shown in FIG. 3, subsequent to recessing the VFET region 10 of the substrate 100, an insulating layer 140 may be formed on a sidewall of the VFET region 10, e.g., the sidewall formed during the recessing. The insulating layer 140 may be formed of any of the materials mentioned in connection with the mask layer 102. Forming the insulating layer 140 may comprise depositing a conformal insulating layer in the VFET region 10 and the HFET region 20. A conformal layer deposition may for instance be achieved by ALD. Thereafter, portions of the conformal insulating layer deposited on horizontally oriented surfaces may be removed by a vertical anisotropic etch step, such that the insulating layer 140 remains on the sidewall. The insulating layer 140 may define a physical and electrical separation between the layer structures of the VFET and the HFET regions 10, 20 and further act as a mask during subsequent epitaxial growth processes discussed in the following.

With reference to FIG. 4, an epitaxial layer structure has been formed in the recessed VFET region 10. The layer structure comprises a lower semiconductor layer 111, an intermediate semiconductor layer 113 above the lower layer and an upper semiconductor layer 115 above the intermediate semiconductor layer 113. Each one the semiconductor layers 111, 113, 115 may for instance be formed by CVD, physical vapor deposition (PVD) or metal-organic vapor phase epitaxy (MOVPE).

The semiconductor layers 111, 113, 115 form part of a first layer structure provided in the VFET region 10. Meanwhile, the (non-recessed portion of the) semiconductor layer 121 of the substrate 100 forms part of a second layer structure in the HFET region 20. The first layer structure is formed with a vertical dimension (e.g., a height) to define an upper surface being coplanar with an upper surface of the second layer structure HFET region 20.

Various compositions of the first and second layer structures are possible. For example, each one of the semiconductor layers 111, 113, 115 of the first layer structure may be formed of a different semiconductor material. At least the intermediate semiconductor layer 113 may be formed of a material different from a material of the upper semiconductor layer 115 and different from a material of the lower semiconductor layer 111. According to one advantageous layer structure, the lower layer may be a Si₁₋ₓGeₓ layer, the intermediate layer may be a Si_{1-y}Ge_{y} layer, and the upper layer may be a Si_{1-z}Ge_{z} layer, wherein 0<x≤1, 0<z≤1 and 0≤y<x, z. The Ge-content of the lower semiconductor layer 111 and upper semiconductor layer 115 may for instance be in the range of 10 to 90% (i.e., 0.1≤x≤0.9 and 0.1≤z≤0.9), or more preferably 20 to 30% (i.e., 0.2≤x≤0.3 and 0.2≤z≤0.3), while the intermediate semiconductor layer 113 may be a layer formed of, or consisting essentially of Si (i.e., y=0). For instance, a layer structure comprising an intermediate semiconductor layer 113 comprising or consisting essentially of Si and having a lower Ge content than lower and upper semiconductor layers 111, 115 may among others facilitate subsequent gate formation steps, as will be further described below.

The lower semiconductor layer 111 may be doped such that the lower semiconductor layer 111 may be used to define lower source/drains for the VFET devices that are to be formed. The upper semiconductor layer 115 may be doped such that the upper layer 115 may be used to define upper source/drains for the VFET devices. The lower semiconductor layer 111 and the upper semiconductor layer 115 may be doped with an n- or p-type dopant, depending on the conductivity type of the device that is to be formed. The intermediate semiconductor layer 113 may be an un-doped layer, or a lightly doped layer, depending on whether an inversion mode (IM) or junction-less (JL) type of VFET device is desired. The layers may be provided with dopants as appropriate e.g., by in-situ doping or using ion implantation steps subsequent to each respective layer formation.

Meanwhile, the second semiconductor structure comprising the semiconductor layer 121 of the substrate 100 (remaining un-recessed in the HFET region 20) may advantageously be a Si-layer, although a SiGe-layer also is possible. The Si- or SiGe-layer may be doped in accordance with the intended conductivity type of the device that is to be formed, or undoped.

In FIG. 5, the mask 102 has been removed in the HFET region 20, thereby exposing the upper surface of the HFET region 20 (e.g., formed by the upper surface of the semiconductor layer 121). The insulating layer 140 may remain to define an insulating boundary between the VFET region 10 and the HFET region 20. The mask 102 may be removed by etch back (by wet- or dry-etching) and/or polishing, for instance by chemical mechanical polishing (CMP). The use of polishing makes it possible to make the upper surfaces of the VFET region 10 and HFET region 20 co-planar, should the upper surface of the first semiconductor structure in the VFET region 10 not be completely flush with the upper surface of the second semiconductor structure in the HFET region 20 following the epitaxy thereof. In any case, the substrate 100 may at the stage shown in FIG. 5 be provided with a common planar upper surface extending throughout the VFET region 10 and the HFET region 20.

### Semiconductor Structure Patterning

FIGS. 6-8 show perspective views of intermediate structures illustrating process steps relating to the semiconductor structure patterning, which comprises forming a number of first semiconductor structures 110 for VFET devices in the VFET region 10 and a number of second semiconductor structures 120 for HFET devices in the HFET region 20.

In FIG. 6, a mask layer 131 has been formed above the planar surface of the substrate 100. The mask layer 131 may for instance comprise a resist-based mask or a litho-stack 131. As shown, a capping layer 130 may be formed prior to the mask layer 131. The capping layer 130 may for instance be formed by a nitride-layer, such as SiN or some other material conventionally used for capping such as SiOC or SiO₂. Further examples include an anti-reflective coating (e.g., a bottom anti-reflective coating or BARC), a hard mask or a suitable patterning film.

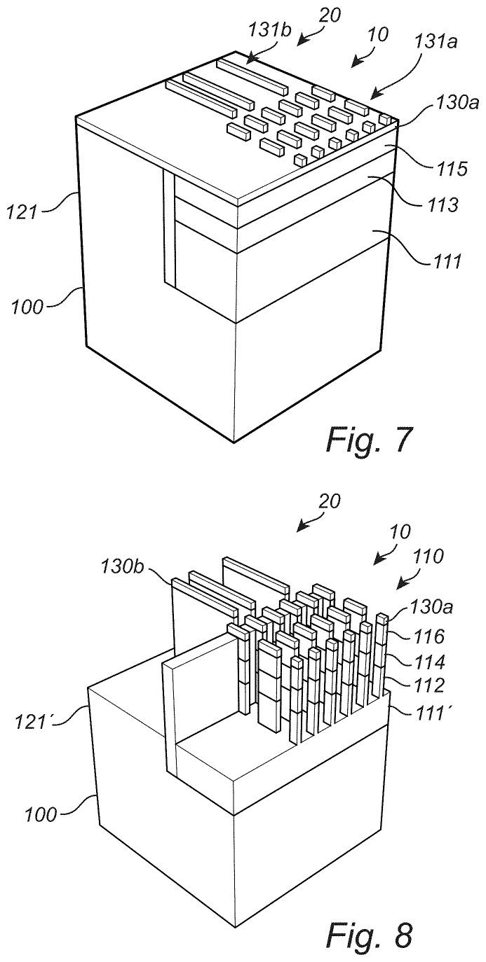

In FIG. 7, the mask layer 131 has been patterned to define a number of discrete first semiconductor structure mask portions 131a above the VFET region 10 and a number or discrete second semiconductor structure mask portions 131b above the HFET region 20. The mask layer 131 may be patterned using lithography, and possibly followed by etching if the mask layer 131 is formed by a litho-stack.

In FIG. 8, the first layer structure in the VFET region 10 and the second layer structure in the HFET region 20 have been patterned in an etching step applied simultaneously to the first layer structure and the second layer structure. During the etching, the mask portions 131a, 131b may act as an etch mask such that a number of first semiconductor structures 110 are formed in VFET region 10 and a number of second semiconductor structures 120 are formed in the HFET region 20. However, it is also possible to first transfer the pattern formed by the mask portions 131a, 131b into the capping layer 130 in a first etch step, to define capping layer portions 130aa, 130ab. Then, in a subsequent step, the semiconductor structures may be etched using the mask portions 131a, 131b and the capping layer portions 130aa, 130ab as a combined etch mask. Any conventional wet- or dry-etching process suitable for semiconductor patterning may be used.

Each first semiconductor structure 110 comprises a lower layer portion 112, an intermediate layer portion 114 and an upper layer portion 116, said portions being formed by remaining portions of respective original lower, intermediate and upper semiconductor layers 111, 113, 115. Each second semiconductor structure 120 comprises a portion of the semiconductor layer 121.

Following the etching, the mask portions 131a, 131b may be removed. As shown, the first and second semiconductor structures 110, 120 may however remain capped by the capping layer portions 130a, 130b, formed by the remaining portions of the capping layer 130.

As shown, the first semiconductor structures 110 may be formed as vertically oriented nanosheets, e.g., having an oblong rectangular cross-sectional shape. However, it is also possible to form the first semiconductor structures 100 as vertically oriented nanowires, e.g., with a square or rounded cross-sectional shape. Meanwhile, the second semiconductor structures 120 may as shown be formed as elongated fin-shaped structures. For ease of readability, the first semiconductor structures 110 will in the following be referred to as pillars while the second semiconductor structures will be referred to as fins.

The simultaneous etching of the first and second layer structures may comprise etching back exposed upper surface portions of the first and second layer structures to corresponding vertical levels, such that the pillars and fins 110, 120 present corresponding heights above the etched back surfaces, or, put differently, have upper surface located at corresponding vertical levels above the etched back surfaces.

The etching may be stopped within the lower layer 111 such that a thickness portion of the lower layer 111′ remains un-etched. Accordingly, the pillars 110 may protrude vertically from the remaining etched-back lower layer 111′. Correspondingly, the fins 120 may protrude vertically from a remaining un-etched semiconductor layer portion 121′.

The lower and upper semiconductor layer portions 112, 116 of a pillar 110 may be used for forming the lower and upper source/drains, respectively, of the final VFET, and may therefore hereinafter be referred to as lower source/drain portion 12 and upper source/drain portion 14, respectively. Similarly, the intermediate semiconductor layer portion 114 may be used to accommodate the channel of the final VFET, and may therefore herein after be referred to as channel portion 13. Accordingly, the channel portion 13 is arranged intermediate the source/drain portions 12, 14 and extending vertically between the two. Put differently, the source/drain portions 12, 14 are located at vertically opposite ends of the channel portion 13.

Moreover, due to the above-discussed doping of the lower layer 111, the lower layer portion 111′ may, together with the lower layer portions 112 protruding therefrom, define lower source/drains or lower source/drain regions for the VFETs to be formed. The lower layer 111′ may in the art also be referred to as the bottom electrode layer.

### Bottom Electrode Layer Partitioning

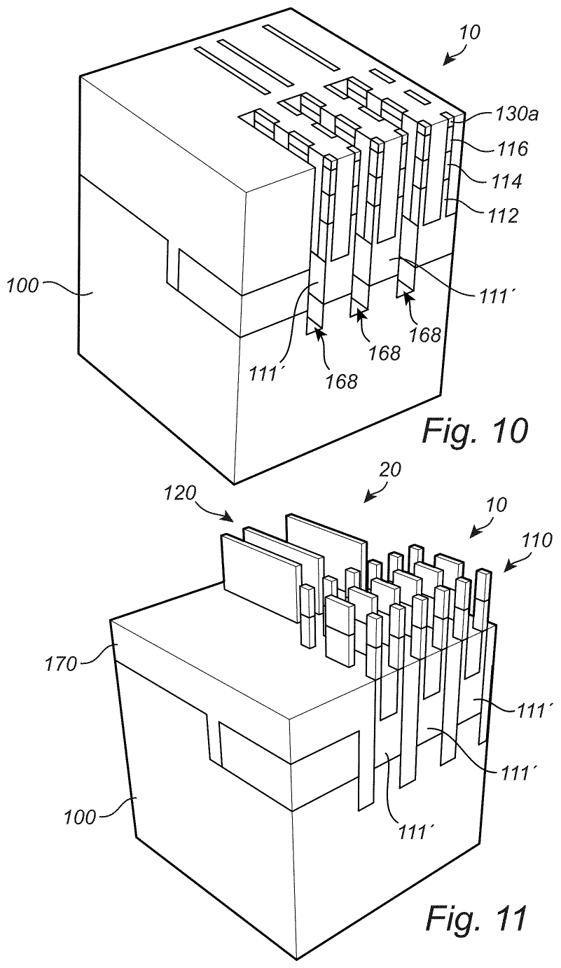

FIGS. 9-10 show perspective views of intermediate structures illustrating show process steps relating to the partitioning or definition of the lower layer/bottom electrode 111′, which comprises, e.g., forming shallow trench isolation or insulation (STI) in the lower layer 111′ in the VFET region 10.

In FIG. 9, the pillars 110 in the VFET region 10 and the fins 120 in the HFET region 20 have been embedded in an insulating layer 182. The insulating layer 182 may for instance be formed of SiO₂, or a suitable low-K dielectric. The insulating layer 182 may be formed by depositing the insulating material (e.g., by CVD), followed by etch back and/or polishing to reduce a thickness of the insulating layer 182 such that the upper surfaces of the pillars 110 and fins 120 are exposed (or as in the illustrated case to expose the caps 130a, 130b formed thereon).

In FIG. 10, trenches 168 have been formed in the bottom electrode layer 111′ in the VFET region 10. The trenches 168 may as shown extend completely through the bottom electrode layer 111′, into an underlying thickness portion of the substrate 100. The bottom electrode layer 111′ may accordingly be partitioned into a number of individual lower layer portions/bottom electrodes 111″. Accordingly, the bottom electrodes 111″ may together with the lower layer portions 112 protruding therefrom, define lower source/drains or lower source/drain regions for the VFETs. In FIG. 10, trenches 168 are formed between every second “row” of pillars 110. This is however merely one example and it is equally possible to form trenches 168 in a less dense manner such that further pillars 110 may share bottom electrodes 111″.

In FIG. 11, the trenches 168 have been filled with an insulating material, thereby separating the bottom electrodes 111″ with STI. The insulating material may for instance be of a same material as the insulating layer 182, and thus be formed in a corresponding manner. Following deposition of the insulating material etch back of the deposited insulating material and the insulating layer 182 may be performed to form a bottom insulating layer 170, embedding bottom parts of the pillars 110 and the fins 120 and the bottom electrodes 111″. The bottom insulating layer 170 may be formed with a thickness such that an upper surface of the insulating layer 170 extends at a vertical level below the channel portions 13 of the pillars 110.

According to a variation, the bottom electrode layer 111′ partitioning may instead be performed at an earlier stage of the process. For instance, trenches corresponding to the trenches 168 may instead be patterned in the lower layer 111 in connection with the patterning of the semiconductor structures 110, 120 wherein the process may proceed directly to gate formation after defining the pillars 110 and fins 120.

### Gate Formation

FIGS. 11 to 24 show perspective views of intermediate structures illustrating process steps relating to the gate formation, which comprises forming of dummy gate structures and subsequent replacement of the dummy gate structures by final gate structures.

FIG. 11 illustrates a perspective view of the semiconductor substrate 100, after the VFET region 10 and the HFET region 20 have been provided with pillars 110 and fins 120, respectively.

In the following, exemplary processing steps for forming gate structures 151, 153 extending along the channel portions 13 of the pillars 110 and across the channel portions 23 of the fins 120 will be discussed. The gates structures 151, 153 may be formed utilizing a replacement metal gate scheme, of which exemplary process steps will be discussed with reference to the following figures.

In FIG. 12, the pillars 110 have been provided with a spacer material 117. The spacer material 117 may be formed by subjecting the semiconductor structures 110 to an oxidation process P, in which an oxide layer is formed. As shown, a spacer in the form of an oxide layer 117 may also be formed on the surface of the fins 120 exposed above the bottom insulating layer 170. In another example, the fins 120 may be protected by a mask counteracting the oxide from being formed on the second semiconductor structure 120 during the oxidation. In a further example, an etch process may be employed to remove oxide from surfaces other than the peripheral surfaces of the source/drain portions 12, 14 of the first semiconductor structures 110.

As disclosed above, the intermediate layer 113, forming the channel portions 13, and the semiconductor layer 121, forming the fins 120, may be formed of materials being different from materials forming the lower and upper layers 111, 115 of the first layer structures in the VFET region 10. For instance, since SiGe has shown to oxidize at much higher rates than Si (in particular at temperatures between 400° C. and 700° C.) forming the lower and upper layers 111, 115 of SiGe and the intermediate layer 113 of Si or SiGe with a lower Ge-content than the lower and upper layer 111, 115, enables a selective or at least preferential oxidation of the upper and lower layer portions 112, 116, such that a thicker oxide layer 117 may be grown on the upper and lower layer portions than on the intermediate layer portion and on the second semiconductor structures 120. The oxide may thus be formed at a temperature and pressure selected such that the thickness of the oxide is growing faster on the upper and lower layer portions than on the intermediate channel portion. In this way a thicker spacer layer may be produced on the peripheral surfaces of the source/drain portions 12, 14 of the pillars 110, and a relatively thin spacer layer, or no spacer layer at all, formed on the peripheral surfaces of the channel portions 13 of the fins 120. A uniform etch of the spacer layer may result in the spacer material being removed from surfaces other than the source/drain portions 12, 14, such as e.g., the channel portions 13 and/or the fins 120.

FIG. 13 schematically illustrates an enlarged cross section of a pillar 110 after the spacer material 117 has been provided. In the present example, the pillar 110 is a pillar formed of upper and lower layer portions 112, 114 and an intermediate layer portion 114, wherein the upper and lower layer portions 112, 114 form the upper and lower source/drain portions 12, 14 and the intermediate layer portion 114 forms the channel portion 13 extending vertically between the source/drain portions 12, 14. During the oxidation process, a spacer 117a has been formed on peripheral surfaces of the part of the lower layer portion 112 that protrudes above the bottom insulating layer 170. Further, a spacer 117c has been formed on peripheral portions of the upper layer portion 116. As indicated in the figure, an oxide layer 117b has also been formed at sidewall portions of the intermediate layer portion 114. Preferably, the oxide layer 117b at the intermediate layer portion 114 is relatively thin compared to the thickness of the spacers 117a, 117c at the lower and upper layer portions 112, 116. Hence, the latter may form a pair of spacers 117a, 117c between which the gate may be aligned vertically, in an accurate manner, with respect to the intermediate layer portion 114 forming the channel portion 13 of the VFET device. Optionally, the oxide layer at the sidewalls of the pillar 110 may etched to remove or at least further reduce the thickness of the oxide layer 117c at the intermediate layer portion 114.

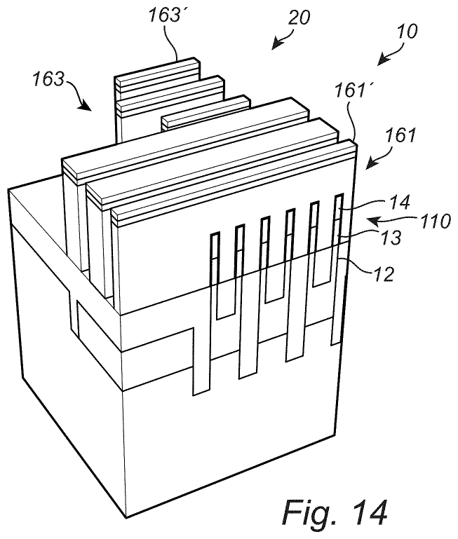

In FIG. 14 a sacrificial or dummy gate layer has been formed above the VFET region 10 and the HFET region 20 of the substrate 100 and patterned, in a simultaneous process over both regions 10, 20, into a set of sacrificial or dummy gates 161, 163. The patterning may be performed by means of a mask structure 161′, 163′, e.g., comprising a hard mask and a nitride layer, as indicated on top of the sacrificial or dummy gates 161, 163, and a suitable conventional wet or dry etching process. The sacrificial or dummy gate layer may for example be formed of amorphous silicon (a-Si). In the VFET region 10 shown in the present figure, three sacrificial or dummy gates 161 may extend in parallel over the pillars 110. A width or lateral dimension of the sacrificial or dummy gates 161 may be such that the sacrificial or dummy gates 161 at least partially enclose the channel portions 13 of the pillars 110, as viewed in a horizontal plane. Preferably, the sacrificial or dummy gates 161 may be formed to completely enclose the channel portions 13, thereby enabling forming of gate-all-around (GAA) VFETs. In the HFET region 20, the sacrificial or dummy gate layer has been patterned to form three parallel sacrificial or dummy gates 163 extending across the fins 120.

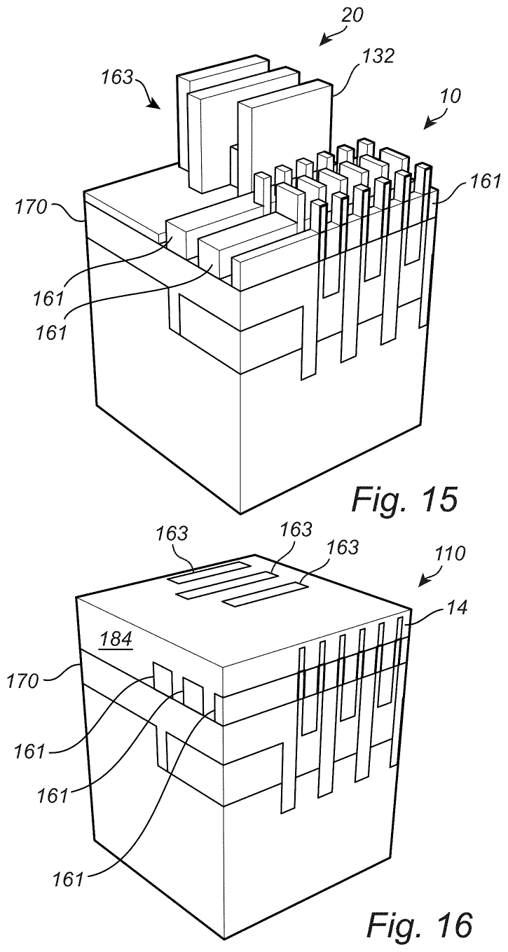

In FIG. 15, the sacrificial or dummy gates 161 in the VFET region 10 have been recessed in an etch back process, to a thickness that may correspond to the gate length of the final VFET device. Preferably, a vertical anisotropic etch process is employed to avoid lateral trimming of the sacrificial or dummy gate 161. During the etching the sacrificial or dummy gates 163 in the HFET region 20 may be protected by an etch mask 132, such as a resist-based mask or a hard mask. The etch mask allows for the sacrificial or dummy gates 161 in the VFET region 10 to be recessed down to a desired thickness while leaving the sacrificial or dummy gates 163 in the HFET region 20 intact. The etch back may be preceded with removal of the afore-mentioned mask structure from the upper surfaces of the sacrificial or dummy gates 161. After the etch back of the sacrificial or dummy gates 161 in the VFET region 10, the etch mask 132 may be removed, as well as the above-mentioned mask structures covering upper surfaces of the sacrificial or dummy gates 163, prior to subsequent processing.

In FIG. 16, the pillars 110 and the fins 120 have been embedded in a dielectric layer 184 of for example SiO₂ or another insulating material, such as a conventional low-k dielectric material. The dielectric layer 184 may be deposited using for instance CVD. The dielectric layer 184 may be etched back and/or polished by for example CMP to reduce the thickness until the upper surface of the sacrificial or dummy gates 163 in the HFET region 20 are exposed. The sacrificial or dummy gates 161 in the VFET region are not exposed yet, due to the previously performed etch back process. Optionally, as disclosed in the present figure, the spacer 117c on the peripheral portions of the upper source/drain portion 14 of the pillars 110 may be removed prior to the forming of the dielectric layer 184. Further, the upper source/drain portion 14 may be formed by replacing the upper layer portion 116 with a source/drain portion 14 that may be epitaxially grown on top of the pillar 110. This process is however not illustrated in the present drawings.

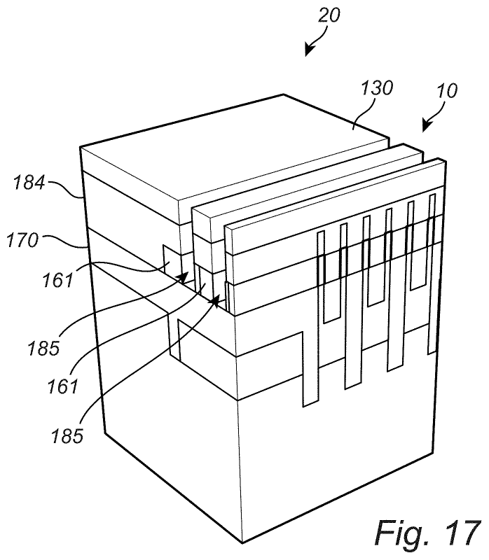

In order to access the sacrificial or dummy gate 161 in the VFET region 10, trenches 185 are formed in the dielectric layer 184. The result is shown in FIG. 17, wherein an etch mask 130, similar to the one previously used in the etch back of the sacrificial or sacrificial or dummy gates 161 in the VFET region 10, has been provided to protect the sacrificial or dummy gates 163 in the HFET region 20 and to define two parallel trenches 185 above and between the three sacrificial or dummy gates 161 in the VFET region 10. The trenches 185 may be formed by etching through the etch mask 130 all the way down to the bottom insulating layer 170. As shown in the present figure, this allows for the sacrificial or dummy gates 161 in the VFET region 10 to be accessed and etched from the side, in the lateral direction.

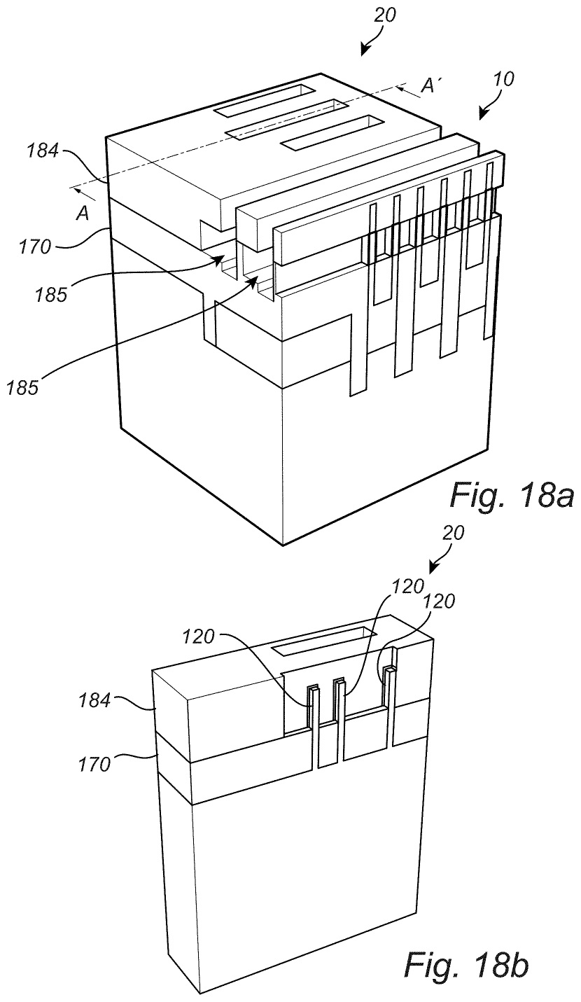

FIGS. 18a to 22b illustrate process steps in which the sacrificial or dummy gates 161, 163 are simultaneously replaced with the final gate structures 151, 153. The “a” figures are perspective views showing a cross section through the pillars 110 in the VFET region 20, and the “b” figures are cross sections taken along the gate tracks in the HFET region.

In FIGS. 18a and 18b the sacrificial or dummy gates 161 in the VFET region 10 and the sacrificial or dummy gates 163 in the HFET region 20 have been removed in a common etch process. The sacrificial or dummy gates 161 in the VFET region 10 have been etched through the trenches 185 formed in the dielectric layer 184 in the VFET region 10, whereas the sacrificial or dummy gates 163 in the HFET region 20 have been etched from the top surfaces exposed in the dielectric layer 184. Optionally, the oxide 117 formed on the surfaces of the fins 120 and at the intermediate layer portion 114 of the pillars 110 during the oxidation process “P” discussed in connection with the example shown in FIGS. 12 and 13 may be removed or at least thinned prior to forming the final gate structures 151, 153.

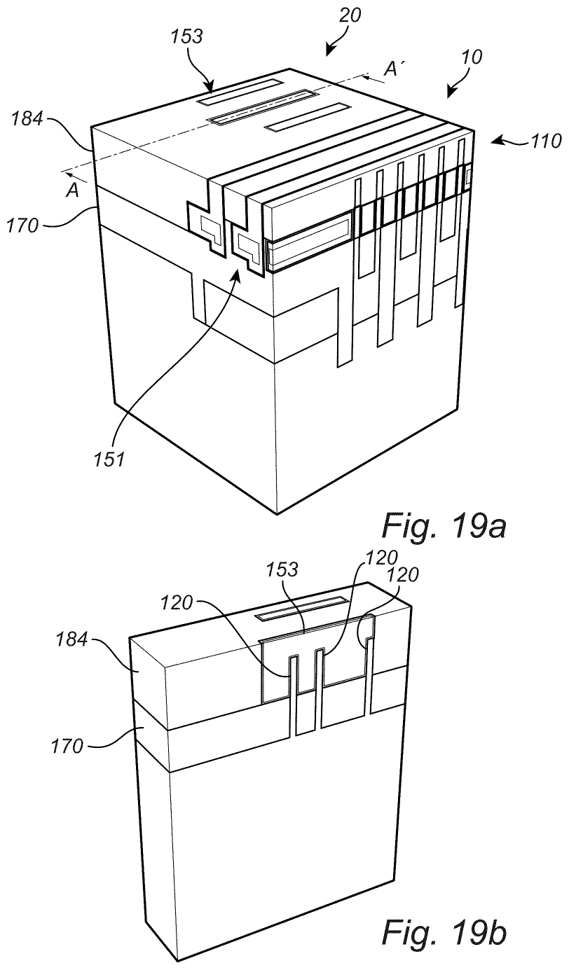

In FIGS. 19a and 19b gate layers have been deposited in place of the sacrificial or dummy gates 161, 163 to form gate structures 151 in the VFET region 10 and gate structures 153 in the HFET region 20. The gate layers may be formed around the pillar 110 and across the fin 120, and may include a gate dielectric layer formed by any conventional gate dielectric material such as HfO₂, ZrO₂, Al₂O₃ or some other high-K dielectric material. The gate dielectric layer may be deposited as a conformal thin film by any conventional deposition process, for instance by ALD. The gate layers may further comprise at least a first conductive layer that is subsequently formed on the gate dielectric layer. The first conductive layer may be formed by an effective work function metal (EWF). The first conductive layer may for instance be formed by one or more p-type EWF metals such as TiN, TaN, TiTaN or by one or more n-type EWF metals such as Al, TiAl, TiC, or TiAlC, or compound layers such as TiN/TiAl or TiN/TaN/TiAl. The first conductive layer may be deposited by any conventional deposition process, for instance by ALD, CVD or PVD. The gate layers may further include a second conductive layer, for instance of W, Al, Co, Ni, Ru or an alloy of two or more of said materials, to provide a gate electrode with the desired electrical properties. The second conductive layer may be deposited by any conventional deposition process, for instance by CVD or by electro-plating. The gate structures 151, 153 may be formed simultaneously in process that is common for the VFET region 10 and the HFET region 20. Alternatively, the gate structures 151, 153 may be formed partly in a process that is common for both regions 10, 20 and partly in processes that are specific for the respective regions 10, 20. Examples of the latter may include a common and simultaneous forming of one or several of the gate layers, followed by an additional processing in only one of the regions 10, 20.

The deposition of the gate layers may be followed by for example a CMP process so as to expose an upper surface of the gate structures 151, 153 and enable subsequent processing.

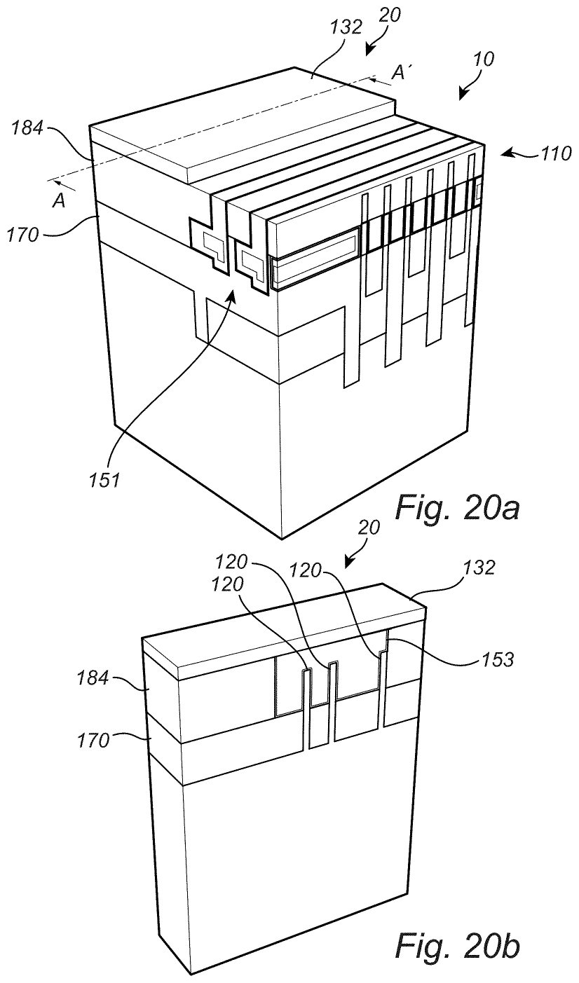

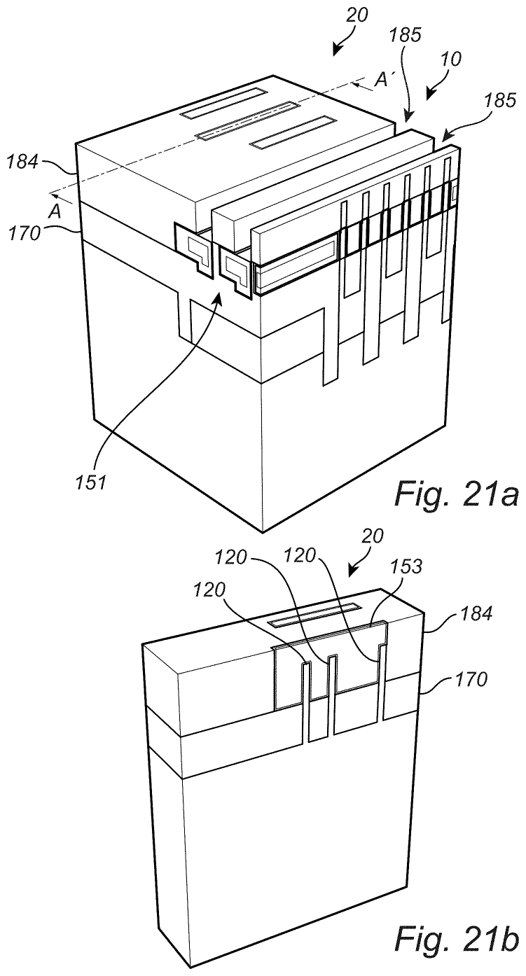

In FIGS. 20a and 20b, the HFET region 20 have been covered by a protecting etch mask portion 132, so as to allow the gate structures 151 in the trenches 185 of the dielectric layer 184 in the VFET region 10 to be recessed. The recessing may comprise wet or dry etching gate metal and gate dielectric material forming the gate structures 151. The result is shown in FIGS. 21a and b.

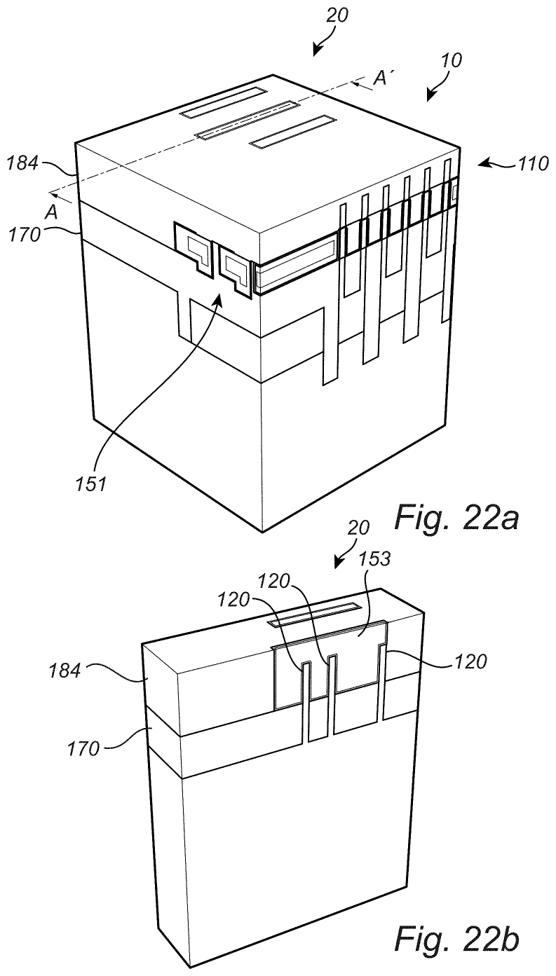

In FIGS. 22a and 22b, the trenches 185 in the VFET region 10 have been filled with a dielectric, e.g., of a same material as the dielectric layer 184, to those again “close” the dielectric layer 184, thereby leaving the gate structures 151 of the VFET devices covered with dielectric.

The upper source/drain portions 12 of the VFET devices in the VFET region 10 may be accessed electrically from above. In FIG. 23 an etch mask 130 has been formed, which is arranged to protect the HFET region 20 from being etched and to define source/drain contact structures in the VFET region 10.

In FIG. 24 the source/drain contact structures 155, which also may be referred to as “top electrodes”, have been formed by etching through the etch mask 130 down to the upper source/drain portions 14 of the VFET devices and filling the trenches with a contact metal, such as for example Al, Co, Ni, W or Ru. Optionally, the deposition of contact metal may be preceded by epitaxially growing doped semiconductor material on the upper source/drain portions 14, to form enlarged upper source/drain portions for improved electrical contact with the source/drain contact structures 155. Alternatively, the top electrodes 155 may be formed by depositing and patterning a metal layer on the upper source/drain portion 14, and then cover the patterned layer with a dielectric material. The lower source/drain portions 12 of the VFET devices may be electrically connected in a conventional manner, for instance by forming vertical conductive vias in contact with the bottom electrodes 111″, e.g., in a region outside of the illustrated section.

Source/drains may also be epitaxially grown on the fins 120, which subsequently may be contact with corresponding source/drain contact structures in a manner which per se is known in the art, thereby completing formation of finFET devices in the HFET region 20.

In the above the inventive concept has mainly been described with reference to a limited number of examples. However, as is readily appreciated by a person skilled in the art, other examples than the ones disclosed above are equally possible within the scope of the inventive concept, as defined by the appended claims. Although in the above, the first layer structure comprises three layers it is also possible to form a first layer structure in a corresponding manner comprising more than three layers, wherein a pillar 110 may be formed comprising a channel portion arranged between one or more lower semiconductor layer portions (e.g., SiGe layers with different Ge-content) and one or more upper semiconductor layer portions (e.g., SiGe layers with different Ge-content).

Additionally or alternatively, the second layer structure of the HFET region 20 may comprise more than one semiconductor layer, such as a stack of an upper epitaxial semiconductor channel layer (e.g., of Si) on a lower epitaxial semiconductor sacrificial layer (e.g., of SiGe), or repetitions of such a stack. Such a dual- or multi-layered structure may be used to form stacked horizontal NWFETs or NSFETs by removing the sacrificial layer(s) prior to gate formation in a selective etch, as per se is known in the art. Accordingly, the second layer structure may comprise at least two epitaxially grown semiconductor layers (e.g., a sacrificial layer and a channel layer) of different materials (e.g., Si₁₋ₐGeₐ and Si_{1-b}Ge_{b} where a≠b). Depending on the relative thicknesses of the first and second layer structures, recessing may be performed in either of the VFET region 10 and the HFET region 20 such that the first and second layer structures may be formed with co-planar upper surfaces. For instance, if the constituent layers of the second layer structure are to be formed with thicknesses such that a height of the second layer structure would exceeds a height of the first layer structure if both were grown on a common planar surface, the method may comprise, prior to forming the second layer structure, recessing the HFET region 20 of the substrate 100 to a depth corresponding to said height difference of the first and second layer structures. The second layer structure may thereafter be formed in the recessed HFET region 20. The first layer structure may be formed in the non-recessed VFET region 10. The method may thereafter proceed with patterning of the pillars 110 in the VFET region 10 and the fins 120 in the HFET region, as set out above.

Additionally, although the method above comprises a RMG flow, a gate-first approach is also possible. That is, the “final” gate structures comprising the gate metals may be formed without any preceding dummy gate formation. As may be appreciated by the skilled person, in a gate-first approach the gate structures may be formed by depositing gate dielectric and metal layers in the VFET and HFET regions 10, 20 and subsequently patterning gate structures for the VFETs and HFETs along the respective channel portions, in a number of metal and dielectric etch steps. Similar to the above-discussed recessing of the dummy gates in the VFET region 10, a selective recessing of the gate structures in the VFET region 10 may be performed to define the gate length for the VFETs. The method may thereafter proceed with top contact formation as set out above.

What is claimed is:

1. A method of fabricating a semiconductor device, the method comprising:
providing a semiconductor substrate, comprising:
providing, in a vertical channel field-effect transistor (FET) device region, a first layer structure comprising a lower semiconductor layer, an intermediate semiconductor layer over the lower semiconductor layer and an upper semiconductor layer over the intermediate semiconductor layer, and
providing, in a horizontal channel FET device region, a second layer structure comprising at least one semiconductor layer,
wherein the first layer structure and the second layer structure have different compositions, and wherein a surface of the semiconductor substrate in the vertical channel FET device region is coplanar with a surface of the semiconductor substrate in the horizontal channel FET device region;
forming a mask defining a first semiconductor structure mask portion over the vertical channel FET device region and a second semiconductor structure mask portion over the horizontal channel FET device region; and
patterning the first layer structure and the second layer structure by simultaneously etching the first layer structure and the second layer structure using the mask as an etch mask, thereby forming:
a first semiconductor structure for a vertical channel FET device in the vertical channel FET device region, the first semiconductor structure comprising a lower layer portion, an intermediate layer portion and an upper layer portion, and
a second semiconductor structure for a horizontal channel FET device in the horizontal channel FET device region.

2. The method according to claim 1, wherein the compositions of the first and second layer structures at least differ by:
having different numbers of layers;
the first layer structure comprising at least one layer formed of a different material than the second layer structure; or
when the first and second layer structures have the same number of layers, a vertical level of an interface between an adjacent pair of layers of the first layer structure falls within a layer of the second layer structure.

3. The method according to claim 1, wherein simultaneous etching comprises etching back exposed surface portions of the first and second layer structures to a common vertical level, such that the first and second semiconductor structures have corresponding heights above the common vertical level.

4. The method according to claim 1, wherein the layers of the first layer structure are epitaxially grown semiconductor layers and the second layer structure comprises at least two epitaxially grown semiconductor layers, and wherein the method further comprises recessing the semiconductor substrate in at least one of the vertical channel FET device region or the horizontal channel FET device region such that an upper surface of the epitaxially grown semiconductor layers of the first semiconductor structure and an upper surface of the epitaxially grown semiconductor layers of the second layer structure form co-planar upper surfaces.

5. The method according to claim 1, wherein forming the first layer structure in the vertical channel FET device region comprises:
recessing the semiconductor substrate in the vertical channel FET device region; and
subsequently epitaxially growing the first layer structure comprising lower, intermediate and upper semiconductor layers such that an upper surface of the first layer structure becomes coplanar with the surface of the semiconductor substrate in the horizontal channel FET device region.

6. The method according to claim 4, further comprising, prior to growing the first layer structure, forming an insulating layer on a sidewall of the substrate formed during recessing of the semiconductor substrate.

7. The method according to claim 1, further comprising:
forming, in the vertical channel FET device region, a first gate structure for the vertical channel FET device, the first gate structure extending along a channel portion formed by an intermediate layer portion of the first semiconductor structure; and
forming, in the horizontal channel FET device region, a second gate structure for the horizontal channel FET device, the second gate structure extending along a channel portion of the second semiconductor structure.

8. The method according to claim 7, further comprising:
forming a bottom insulating layer embedding respective bottom portions of the first and second semiconductor structures and having an upper surface extending at a vertical level below the intermediate layer portion of the first layer structure; and
subsequently forming the first and second gate structures on the bottom insulating layer.

9. The method according to claim 7, further comprising recessing the first gate structure in the vertical channel FET device region to define a gate length of the vertical channel FET device.

10. The method according to claim 9, wherein upper surfaces of the first and second gate structures, prior to recessing, are located at corresponding vertical levels.

11. The method according to claim 7, wherein forming the first and second gate structures comprises simultaneously patterning a gate layer formed in the vertical channel FET device region and in the horizontal channel FET device region.

12. The method according to claim 7, wherein the first and second gate structures comprise respective gate electrodes.

13. The method according to claim 7, wherein the first and second gate structures are sacrificial gate structures comprising respective sacrificial gates, wherein the method further comprises:
subsequent to recessing the sacrificial gate of the first sacrificial gate structure to define a gate length of the vertical channel FET device, embedding the first and second semiconductor structures in a dielectric layer having a height exposing an upper surface of the sacrificial gate of the second sacrificial gate structure and covering an upper surface of a recessed sacrificial gate of the first sacrificial gate structure;
forming a trench in the dielectric layer to expose the sacrificial gate of the vertical channel FET device region; and
simultaneously replacing the respective sacrificial gates of the first and second sacrificial gate structures with respective gate electrodes.

14. The method according to claim 7, wherein the intermediate semiconductor layer is formed of a material different from a material of the lower semiconductor layer and/or a material of the upper semiconductor layer, and the method further comprises, prior to forming the first gate structure, forming a spacer on peripheral surfaces of the lower layer portion and the upper layer portion.

15. The method according to claim 14, wherein forming the spacer comprises:
subjecting the first semiconductor structure to an oxidation process, thereby forming an oxide layer on the peripheral surfaces of the lower layer portion and the upper layer portion and on peripheral surfaces of the intermediate layer portion, wherein the lower and upper layer portions are provided with thicker oxide layer portions than the channel portion.

16. The method according to claim 1, wherein the lower layer comprises Si₁₋ₓGeₓ, the intermediate layer comprises Si_{1-y}Ge_{y}, and the upper layer comprises Si_{1-z}Ge_{z},
wherein 0<x, z≤1 and 0≤y<x, z.

17. The method according to claim 16, wherein the intermediate layer is a silicon layer and the lower and upper layers have a Ge content of 10-90%.
